(19) United States
(12) Patent Application Publication
(10) Pub. No.: US 2015/0280041 A1
(43) Pub. Date: Oct. 1, 2015

(54) CONCENTRATED PHOTOVOLTAIC MODULE

(71) Applicants: KOREA ELECTRONICS TECHNOLOGY INSTITUTE, Gyeonggi-do (KR); ELECTRONICS AND TELECOMMUNICATIONS RESEARCH INSTITUTE, Daejeon (KR)

(72) Inventors: Hyung Man Lee, Seongnam-si (KR); Seok Hwan Moon, Daejeon (KR)

(73) Assignees: KOREA ELECTRONICS TECHNOLOGY INSTITUTE, Seongnam-si, Gyeonggi-do (KR); ELECTRONICS AND TELECOMMUNICATIONS RESEARCH INSTITUTE, Daejeon (KR)

(21) Appl. No.: 14/432,681

(22) PCT Filed: Sep. 17, 2013
(86) PCT No.: PCT/KR2013/008393

§ 371 Date: Mar. 31, 2015

(30) Foreign Application Priority Data
Sep. 28, 2012 (KR) 10-2012-0108748

(51) Int. Cl. H01L 31/052; H01L 31/054

(52) U.S. Cl. CPC H01L 31/0521; H01L 31/0543

(57) ABSTRACT

The present invention relates to a concentrated photovoltaic module and, more particularly, to a concentrated photovoltaic module that is capable of efficiently dissipating the heat generated in a solar cell to the atmosphere. The concentrated photovoltaic module according to the present invention includes: a concentrated lens array module having at least one condenser lens; a solar cell positioned at the lower end of the condenser lens; a substrate positioned at the lower end of the solar cell and supplied with the heat generated in the solar cell; a flat plate-type heat pipe positioned at the lower end of the substrate; a flat plate-type heat sink positioned at the lower end of the flat plate-type heat pipe; and a condenser lens array structure fixing the condenser lens array module to the substrate.

### TECHNICAL FIELD

This invention relates to a concentrated photovoltaic module and, more particularly, to a concentrated photovoltaic module that is capable of efficiently dissipating heat generated in a solar cell to the atmosphere.

### BACKGROUND ART

In general, a light condensing unit of a photovoltaic generation system includes a condensing lens which condenses sunlight, a solar cell which absorbs and converts condensed sunlight into electric energy, a photovoltaic module in which the solar cells are connected in series or parallel, a frame which connects and supports the condensing lens and the photovoltaic module, and a heat radiation means which cools the photovoltaic module heated by the condensed sunlight.

The solar cell is manufactured of a semiconductor element such as silicon (Si) or the like, and uses a principle in which, when light energy (photon) is input, electrons are moved, currents flow, and thus electricity is generated. In the solar cell, one surface is formed of an n(negative)-conductive material, and other surface is formed of a p(positive)-monocrystalline, polycrystalline, or amorphous conductive silicon plate.

As described above, the photovoltaic module which is a solar cell assembly is a light condensing medium on which sunlight is directly scanned for a long period of time. In the case of the middle of the day in the mid-summer when intense sunlight is blazing down, a considerably high temperature of 60 to 70° C. or more is generated. Generation of the high temperature deteriorates efficiency of the photovoltaic module. In severe cases, the generation of the high temperature causes a breakdown, a damage and a loss of function. In consideration of Korean weather characteristics in which seasonal variations are pronounced and a temperature difference between summer and winter is maximally 30 to 40° C. or more, proper measures with respect to these problems are required.

The solar cell of the photovoltaic module performs generation of electricity at only a certain temperature range. When the solar cell is overheated to a predetermined temperature or more, a function thereof is sharply lowered, and an operation of a control circuit thereof is stopped. Therefore, the heat radiation means is provided to cool the overheated solar cell and to maintain the solar cell within a predetermined temperature range.

FIG. 1 illustrates a conventional concentrated photovoltaic module. Hereinafter, the conventional concentrated photovoltaic module will be described with reference to FIG. 1.

Referring to FIG. 1, the conventional concentrated photovoltaic module includes a condensing lens, a solar cell, a substrate, a heat pipe, and a connecting member. Of course, another element other than above-described elements may be included in the concentrated photovoltaic module.

It may be understood that the conventional concentrated photovoltaic module uses the cylinder-shaped heat pipe 10. Therefore, there is a disadvantage in that the connecting member 20 should be separately provided to use the cylinder-shaped heat pipe 10 on the substrate 30. Since the heat pipe and the substrate are coupled using the separate connecting member, a manufacturing cost of the concentrated photovoltaic module is increased. Therefore, a new method for reducing the manufacturing cost of the concentrated photovoltaic module is required.

### SUMMARY OF INVENTION

### Technical Problem

The present invention is directed to providing a concentrated photovoltaic module which is capable of reducing a manufacturing cost thereof.

Also, the present invention is directed to providing a concentrated photovoltaic module which is capable of reducing the number of components thereof.

Also, the present invention is directed to providing a concentrated photovoltaic module which is capable of effectively arranging a solar cell under a condensing lens.

### Solution to Problem

One aspect of the present invention provides a concentrated photovoltaic module including a condensing lens array module having at least one condensing lens, a solar cell positioned at a lower end of the condensing lens, a flat plate-type heat pipe positioned at a lower end of the solar cell, and a flat plate-type heat sink positioned at a lower end of the flat plate-type heat pipe.

Another aspect of the present invention provides a concentrated photovoltaic module including a condensing lens array module having at least one condensing lens, a solar cell positioned at a lower end of the condensing lens, a substrate positioned at a lower end of the solar cell and supplied with heat generated in the solar cell, a flat plate-type heat pipe positioned at a lower end of the substrate, a flat plate-type heat sink positioned at a lower end of the flat plate-type heat pipe, and a condensing lens array structure configured to fix the condensing lens array module to the substrate.

### Advantageous Effects of Invention

Since the present invention uses the flat plate-type heat pipe, the separate connecting member which connects the photovoltaic module and the heat pipe in the prior art is not used, and thus the manufacturing cost of the concentrated photovoltaic module can be reduced. Also, since the present invention uses the flat plate-type heat pipe, the heat generated in the solar cell can be efficiently dissipated to the atmosphere.

Also, since the present invention uses the flat plate-type cooling structure, the aligning process with the photovoltaic module including the upper condensing lens array module and the lower flat plate-type cooling structure can be simplified, and thus a module manufacturing cost can be reduced.

### BRIEF DESCRIPTION OF DRAWINGS

FIG. 1 illustrates a conventional concentrated photovoltaic module.

FIG. 2 illustrates a concentrated photovoltaic module having a cooling structure in accordance with one embodiment of the present invention.

FIG. 3 illustrates a concentrated photovoltaic module having a cooling structure in accordance with one embodiment of the present invention.

FIG. 4 illustrates a concentrated photovoltaic module having a cooling structure in accordance with one embodiment of the present invention.

FIG. 5 illustrates a concentrated photovoltaic module having a cooling structure.

FIG. 6 illustrates a flat plate-type heat pipe in accordance with one embodiment of the present invention.

FIG. 7 illustrates a condensing lens module in accordance with one embodiment of the present invention.

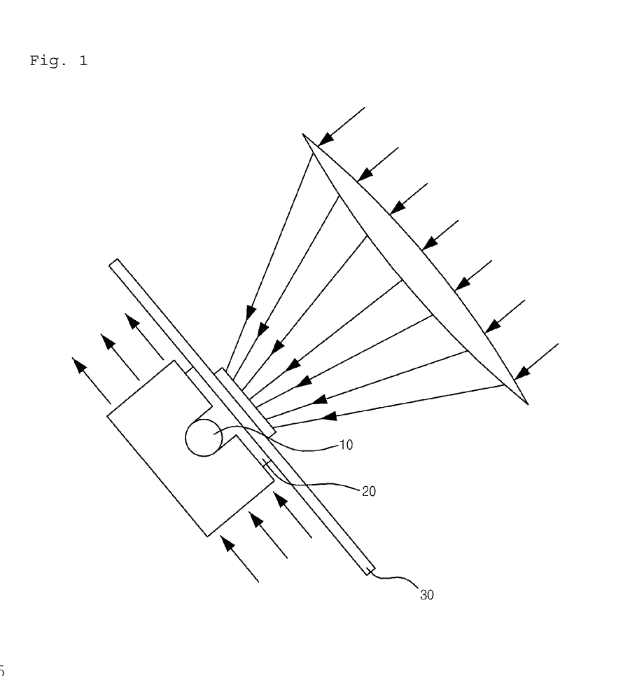

Detailed Description of Main Elements

| | |
|---|---|
| 101: condensing lens | 102: condensing lens array structure |
| 103: solar cell | 104: package module |
| 105: substrate | 106: flat plate-type heat pipe |
| 107: flat plate-type heat sink | |

### DETAILED DESCRIPTION OF EMBODIMENT

The above-mentioned and additional features of the present invention will become more clearly understood from the following embodiments described with reference to the accompanying drawings. Hereinafter, the following exemplary embodiments are described in order to enable those of ordinary skill in the art to embody and practice the invention.

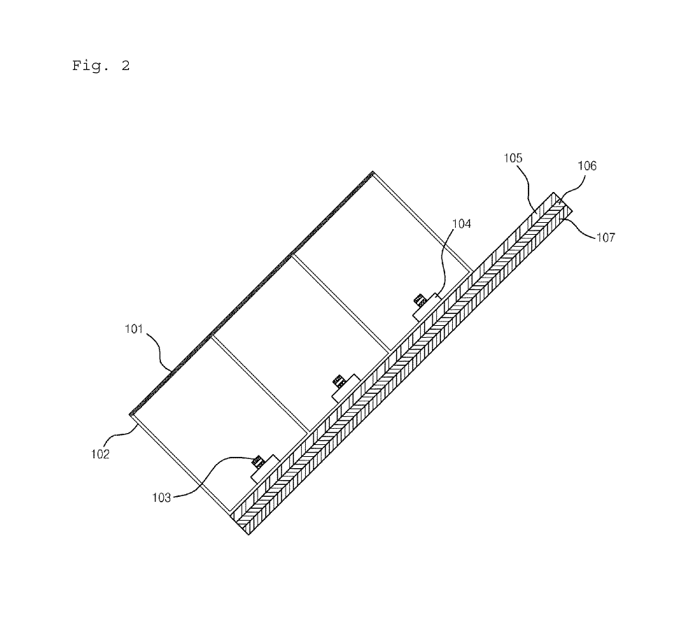

FIG. 2 illustrates a concentrated photovoltaic module having a cooling structure in accordance with one embodiment of the present invention. Hereinafter, the concentrated photovoltaic module having the cooling structure in accordance with one embodiment of the present invention will be described in detail with reference to FIG. 2.

Referring to FIG. 2, the concentrated photovoltaic module includes a condensing lens, a condensing lens array structure, a solar cell, a package module, a substrate, a flat plate-type heat pipe, and a flat plate-type heat sink. Of course, another element other than the above-described elements may be included in the concentrated photovoltaic module.

The condensing lens 101 condenses sunlight introduced from an outside and then radiates the condensed sunlight to the solar cell. The condensing lens array structure 102 is a structure which supports the concentrated photovoltaic module. The solar cell 103 produces electricity using the sunlight radiated from the condensing lens or the sunlight radiated without passing through the condensing lens. The package module 104 has the solar cell attached thereon, and serves to fix the solar cell to the substrate.

The substrate 105 has the package module coupled thereon, and serves to dissipate heat generated by the sunlight introduced from the outside. The flat plate-type heat pipe 106 is formed in a flat plate shape, and serves to dissipate the heat transferred from the substrate to the outside or atmosphere using a material filled therein. In the present invention, the material whose phase changes by the heat is preferably filled in the flat plate-type heat pipe. That is, it is preferable that the material whose phase changes from a liquid state to a gas state by the heat is filled in the flat plate-type heat pipe.

The flat plate-type heat sink 107 is coupled to a lower end of the flat plate-type heat pipe. The flat plate-type heat sink 107 serves to dissipate the heat received from the flat plate-type heat pipe to the outside. As described above, the present invention uses the flat plate-type heat pipe. Therefore, a coupling ability with the package module or the substrate may be enhanced, and a manufacturing process may be also simplified.

In addition, the present invention uses the heat pipe having a flat plate structure. Therefore, two heat transfer members caused by applying a block configured to connect a solar cell assembly part and a heat pipe may be improved, and thus the heat generated in the solar cell may be dissipated using only one heat transfer member. As described above, the present invention may enhance cooling performance through an increase of heat transfer efficiency and may have excellent advantages in a photovoltaic module packaging and manufacturing of a cooling module.

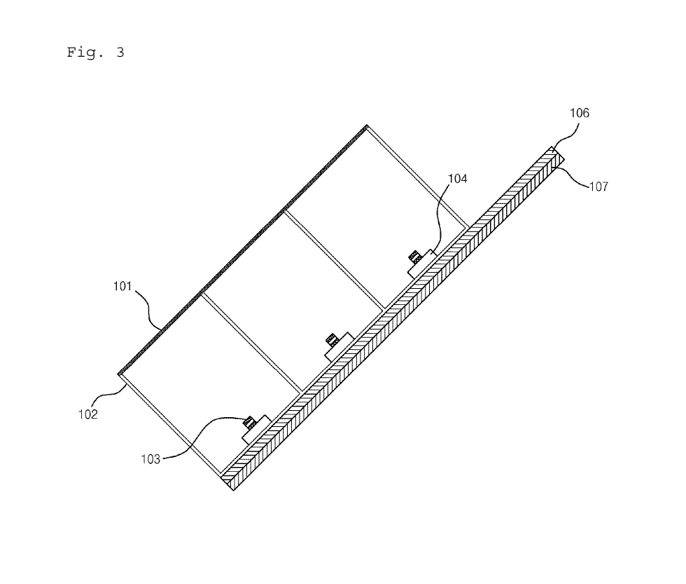

FIG. 3 illustrates a concentrated photovoltaic module having a cooling structure in accordance with one embodiment of the present invention. Hereinafter, the concentrated photovoltaic module having the cooling structure in accordance with one embodiment of the present invention will be described in detail with reference to FIG. 3.

Referring to FIG. 3, the concentrated photovoltaic module includes a condensing lens, a condensing lens array structure, a solar cell, a package module, a flat plate-type heat pipe, and a flat plate-type heat sink. Of course, another element other than the above-described elements may be included in the concentrated photovoltaic module.

The condensing lens 101 condenses sunlight introduced from an outside and then radiates the condensed sunlight to the solar cell. The condensing lens array structure 102 is a structure which supports the concentrated photovoltaic module. The solar cell 103 produces electricity using the sunlight radiated from the condensing lens or the sunlight radiated without passing through the condensing lens. The package module 104 has the solar cell attached thereon, and serves to fix the solar cell to the flat plate-type heat pipe.

The flat plate-type heat pipe 106 is formed in a flat plate shape, and serves to dissipate the heat transferred from the package module to the outside or atmosphere using a material filled therein. In the present invention, the material whose phase changes by the heat is preferably filled in the flat plate-type heat pipe. That is, it is preferable that the material in which the phase changes from a liquid state to a gas state by the heat is filled in the flat plate-type heat pipe.

The flat plate-type heat sink 107 is coupled to a lower end of the flat plate-type heat pipe. The flat plate-type heat sink serves to dissipate the heat received from the flat plate-type heat pipe to the outside. As described above, the present invention uses the flat plate-type heat pipe. Therefore, a coupling ability with the package module or a substrate may be enhanced, and a manufacturing process may be also simplified. As described above, the present invention may remove the substrate, and thus a material cost may be reduced, and also a packing structure may be simplified. That is, the packing module may be directly bonded on the flat plate-type heat pipe, and thus the heat generated in the solar cell may be immediately removed through the flat plate-type heat pipe. Also, the present invention may reduce the number of heat transfer members, and thus may enhance cooling performance. In this case, a supporting frame configured to support the condensing lens formed thereon may be preferably formed at the flat plate-type heat pipe or the flat plate-type heat sink, instead of the substrate.

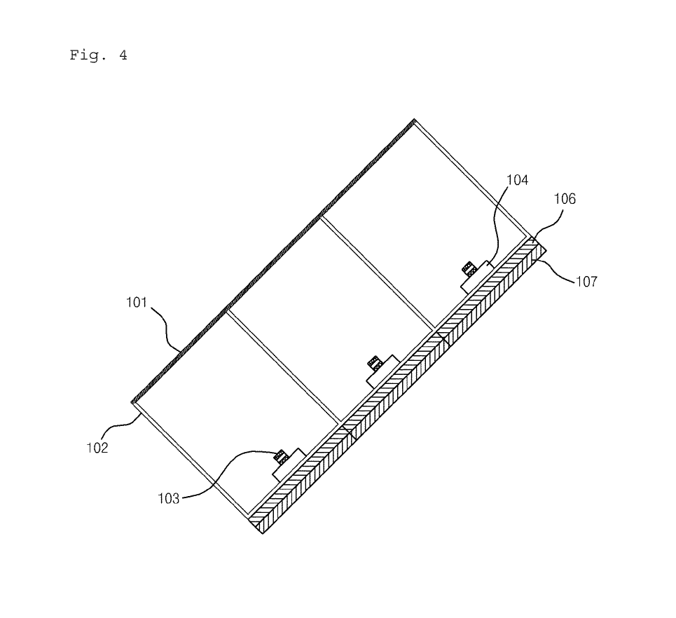

FIG. 4 illustrates a concentrated photovoltaic module having a cooling structure in accordance with one embodiment of the present invention. Hereinafter, the concentrated photovoltaic module having the cooling structure in accordance with one embodiment of the present invention will be described in detail with reference to FIG. 4.

Referring to FIG. 4, unlike FIG. 2 or 3, it may be understood that the concentrated photovoltaic module may be manufactured so that the flat plate-type heat pipe and the flat plate-type heat sink are configured separately for each solar cell and then attached in the form of an array.

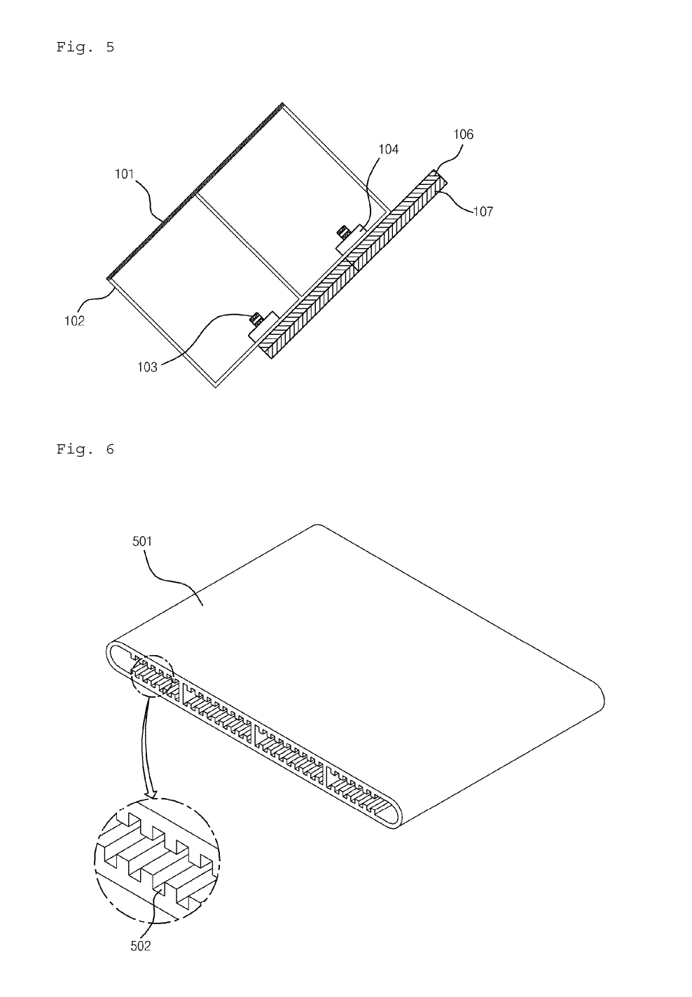

FIG. 5 illustrates a concentrated photovoltaic module having a cooling structure. Hereinafter, the concentrated photovoltaic module having the cooling structure in accordance with one embodiment of the present invention will be described in detail with reference to FIG. 5.

FIG. 5 illustrates the case in which, when the flat plate-type heat pipe and the flat plate-type heat sink are coupled with the package module to which the solar cell is attached, the package module is located at a position spaced a predetermined distance from a center of the flat plate-type heat pipe and the flat plate-type heat sink, instead of located at the center of the flat plate-type heat pipe and the flat plate-type heat sink.

As described above, in the present invention, the package module may be located at various positions of the flat plate-type heat pipe or the flat plate-type heat sink.

FIG. 6 illustrates a flat plate-type heat pipe in accordance with one embodiment of the present invention. Hereinafter, the flat plate-type heat pipe in accordance with one embodiment of the present invention will be described in detail with reference to FIG. 6.

As described above, the flat plate-type heat pipe has the flat plate-type structure, and a gas-liquid phase changing material is filled therein. Also, the flat plate-type heat pipe is formed of a metallic material, preferably aluminum.

Referring to FIG. 6, a protruding part having a predetermined length is formed at upper and lower inner surfaces of the flat plate-type heat pipe. FIG. 6 illustrates a square-shaped protruding part 502, but the present invention is not limited thereto. That is, the protruding part may be formed in various shapes such as a triangular shape, a square shape and a semi-circular shape. Also, the flat plate-type heat pipe preferably has a connecting part at regular intervals, which connects the upper and lower inner surfaces thereof.

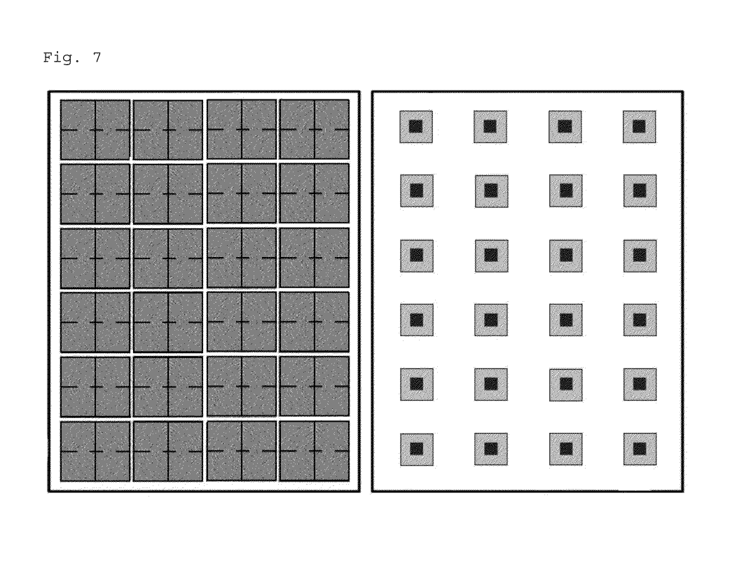

FIG. 7 illustrates a condensing lens array module and a photovoltaic module in accordance with one embodiment of the present invention. Hereinafter, the condensing lens array module and the photovoltaic module in accordance with one embodiment of the present invention will be described in detail with reference to FIG. 7.

The concentrated photovoltaic module essentially requires the condensing lens which condenses the sunlight introduced from the outside using a lens. The present invention may use the flat plate-type heat pipe and the flat plate-type heat sink which have a flat plate-type cooling structure, and may simplify an aligning process with the photovoltaic module including the upper condensing lens array module and the lower flat plate-type cooling structure, thereby reducing a manufacturing cost of the module due to productivity improvement through a mass production process.

In manufacturing the concentrated photovoltaic module, a prior art which is manufactured applying the heat pipe has a structure in which a circular heat pipe and a flat plate-type heat sink provided around the circular heat pipe are used, and thus the condensing lens and the solar cell should be separately aligned. However, since the present invention applies the heat pipe having the flat plate-type structure, the photovoltaic module is bonded to a predetermined precise position which is matched with the upper condensing lens array module, and thus the concentrated photovoltaic module may be manufactured through an automated bonding process and an entire aligning process of the module without the bonding process through an separate cell alignment. Also, according to FIG. 7, only two of the photovoltaic modules are aligned with the condensing lens forming the upper condensing lens array module, and then fixed at the positions, and the solar cells forming the rest photovoltaic modules are aligned with the condensing lenses forming the condensing lens array module without a separate aligning process.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A concentrated photovoltaic module comprising:
a condensing lens array module having at least one condensing lens;
a solar cell positioned at a lower end of the condensing lens;
a flat plate-type heat pipe positioned at a lower end of the solar cell; and
a flat plate-type heat sink positioned at a lower end of the flat plate-type heat pipe.

2. The module of claim 1, wherein a protruding part having a predetermined length is formed at regular intervals from upper and lower inner surfaces of the flat plate-type heat pipe.

3. The module of claim 2, wherein a flat plate-type substrate configured to transfer heat generated from the solar cell to the flat plate-type heat pipe is formed between the lower end of the solar cell and an upper end of the flat plate-type heat pipe.

4. The module of claim 3, comprising a condensing lens array structure configured to fix the condensing lens array module to the flat plate-type heat pipe or the substrate.

5. The module of claim 4, wherein the flat plate-type heat pipe and the flat plate-type heat sink are separately formed for each solar cell, or integrally formed with each other.

6. The module of claim 5, wherein the flat plate-type heat pipe is formed of aluminum, and an inner side thereof is formed of a material whose phase changes from liquid to gas according to a temperature.

7. The module of claim 1, wherein the solar cells are disposed to be spaced the same distance as a spacing distance between the condensing lenses forming the condensing lens array module.

8. A concentrated photovoltaic module comprising:
a condensing lens array module having at least one condensing lens;
a solar cell positioned at a lower end of the condensing lens;
a substrate positioned at a lower end of the solar cell and supplied with heat generated in the solar cell;
a flat plate-type heat pipe positioned at a lower end of the substrate;
a flat plate-type heat sink positioned at a lower end of the flat plate-type heat pipe; and
a condensing lens array structure configured to fix the condensing lens array module to the substrate.
